(19) United States
(12) Patent Application Publication
(10) Pub. No.: US 2024/0080996 A1
(43) Pub. Date: Mar. 7, 2024

(54) Digital Display Device

(71) Applicant: Yisroel Rosner, Lawrence, NY (US)

(72) Inventor: Yisroel Rosner, Lawrence, NY (US)

(21) Appl. No.: 17/902,434

(22) Filed: Sep. 2, 2022

(51) Int. Cl. H05K 5/00; G09F 9/302; G09F 9/33; G09F 9/35

(52) U.S. Cl. CPC H05K 5/0021; G09F 9/302; G09F 9/33; G09F 9/35

(57) ABSTRACT

This invention is preferably a cube-shaped digital display device. The device displays digital images on five sides of the cube. In other embodiments the device could be shaped like a hexagon with six sides, each containing a screen or like a rectangle with three rectangular screens, the fourth being the base, and two square screens, one on each end or the invention may be spherical with one spherical screen. These embodiments may also contain speakers to play sounds. Each screen consists of an extremely high resolution LED or LCD display, especially suited to display non-fungible tokens (NFT's), but also will display a variety of moving and still images including videos, animations, cartoons and GIF's, as well as drawings, figures and photographs. Three dimensional images and virtual reality images may also be displayed The device may sit on a surface, be affixed to the top of a pole, be attached to a wall or may hang like a chandelier. The device may be constructed in a large variety of sizes depending on the intent of the user. Images may wrap around edges, bleeding across screens to travel across edges and appear to travel continuously through the device. The present invention is especially suitable to display advertising, images designed to promote one or more products. Constructing the device to be waterproof would enable use of the device out of doors. The screens may also be constructed to be transparent, revealing the interior of the device (the “skeleton” option).

Data and images may be stored in memory on the device, or may be transmitted by wires or wirelessly through Bluetooth, Wi-Fi, cellular, SIM (Subscriber Identity Module) Card or other similar means. The device may be powered by AC current, batteries or even solar.

### CROSS REFERENCE TO RELATED APPLICATIONS

This application claims priority from Provisional Patent Application Ser. No. 63/341,896 filed on 13 May 2022.

### FIELD OF THE INVENTION

The present invention relates to the field of digital display devices. More particularly, this invention relates to a cube-shaped device that displays digital images on five sides of the cube with the sixth side being the non-displaying base. In other embodiments the device could be shaped like a hexagon with six sides, each containing a screen or like a rectangle with three rectangular screens, the fourth being the base, and two square screens, one on each side. Each screen consists of an extremely high resolution LED or LCD display, especially suited to display non-fungible tokens (NFT's), but also will display a variety of moving and still images including videos, animations, cartoons and GIF's, as well as drawings, figures and photographs. Three dimensional images and virtual reality images may also be displayed The device may sit on a surface, be affixed to the top of a pole, be attached to a wall or may hang like a chandelier. The device may be constructed in a large variety of sizes depending on the intent of the user. Images may wrap around edges, bleeding across screens to travel across edges and appear to travel continuously through the device, creating the impression of a holographic image. The present invention is especially suitable to display advertising, images designed to promote one or more products.

In another embodiment, constructing the device to be waterproof would enable use of the device out of doors. In yet another embodiment, the screens may be constructed to be transparent, revealing the interior of the device (the “skeleton” option).

Data and images may be stored in memory on the device, or may be transmitted by wires or wirelessly through Bluetooth, Wi-Fi, cellular, SIM (Subscriber Identity Module) Card or other similar means. The device may be powered by AC current, batteries or even solar power.

### BACKGROUND OF THE INVENTION

Digital display devices are widely known. Cellphones, computer monitors and even picture frames are widely available to display pictures, diagrams, photographs and the like. The prior art contains numerous examples of digital display devices. For example, devices such as those disclosed by U.S. Pat. No. 11,061,637 to Chowdhury et al, dated Jul. 13, 2021, for a digital picture frame.

Patents such as this show numerous innovations which may be suitable for the specific individual purposes that they address, but are not suitable for the purposes of the present invention as heretofore described.

What is needed is a digital display device with extremely high resolution, capable of displaying separate still images as well as moving images that can travel from side to side, traversing edges, videos and animations that can traverse the edges to move from screen to screen seeming to move through the device. Further, screens are needed that are capable of displaying a collection of images on one screen, one image over several screens, as well as moving images that seem to travel through the device, creating the impression of a holographic image. This configuration would also allow easy comparison of images on the same screen or on different screens.

### SUMMARY OF THE INVENTION

This invention is a digital display device, preferably constructed in the shape of a cube, with five extremely high revolution screens using LCD or LED displays or the like. In other embodiments the device could be shaped like a hexagon with six sides, each containing a screen or like a rectangle with three rectangular screens, the fourth being the base, and two square screens, one on each end. In another embodiment the invention could be shaped like a sphere, with one spherical screen. These embodiments may also contain speakers to play sounds. The displays may show still or moving images and the images may travel from screen to screen, or wrap around or bleed beyond edges to show collections of still images, videos, animations or virtual reality images and holograms. The present invention is especially suitable to display advertising, images designed to promote one or more products.

The device, which will be available in a wide range of sizes, may sit on a surface such as a desk or table, hang on a wall or be supported by a pole or other support such as suspended like a chandelier. Digital images and other data may be self-contained in various memory devices, or may be transmitted through wires or wirelessly via Bluetooth, Wi-Fi, cellular, SIM (Subscriber Identity Module) Card or other similar means. A weather proof embodiment may be constructed to enable use of the device out of doors.

### BRIEF DESCRIPTION OF THE DRAWINGS

The present invention will be described by way of exemplary embodiments, but not limitations, illustrated in the accompanying drawings and photographs in which like references denote similar elements, and in which:

FIG. 1 illustrates an overhead view of the present invention in its cube embodiment, showing five screens, with the sixth side being the base, showing internal components.

FIG. 2 illustrates an overhead view of the present invention in its cube embodiment, showing five screens, with the sixth side being the base, showing internal components.

FIG. 3 illustrates a side view of the present invention in its cube embodiment, showing one screen and internal components.

FIG. 4 illustrates a bottom view of the present invention in its cube embodiment, showing the switch.

FIG. 5 illustrates a wiring diagram of the present invention in its cube embodiment, showing the power connections.

FIG. 6 illustrates the data cable connections of the present invention in its cube embodiment.

FIG. 7 illustrates a bottom view of the present invention in its cube embodiment, showing the data cable connections.

FIG. 8 illustrates a drawing of a top view of the present invention in its cube embodiment, showing images on three screens.

FIG. 9 illustrates a front view of the present invention in its hexagonal embodiment, showing images on three screens.

### DETAILED DESCRIPTION OF THE INVENTION

The present invention will be described by way of exemplary embodiments, but not limitations, illustrated in the accompanying drawings and photographs in which like references denote similar elements, and in which:

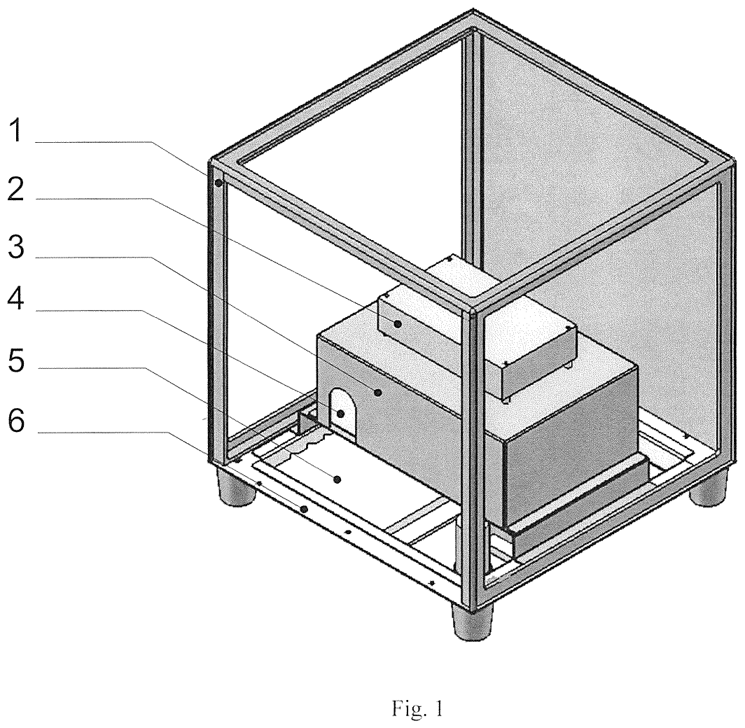

FIG. 1 illustrates an overhead view of the present invention in its cube embodiment, showing five screens, with the sixth side being the base, showing internal components. The digital display device includes a plastic or metal frame 1, a power supply 2, a battery cage 3, a battery 4, a control card Sand a stainless plate 6.

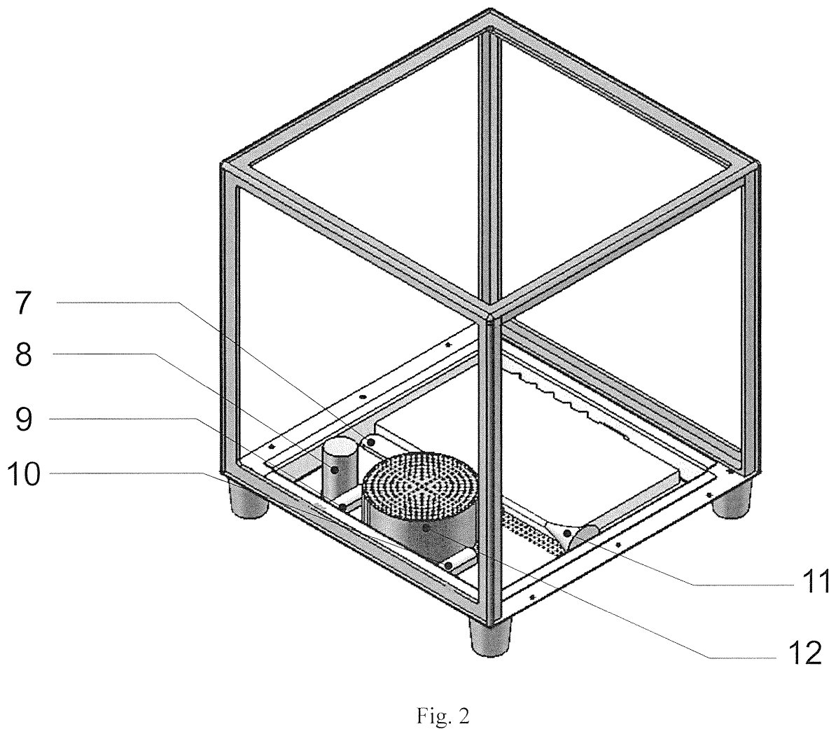

FIG. 2 illustrates an overhead view of the present invention in its cube embodiment, showing five screens, with the sixth side being the base, showing internal components. The digital display device includes a Wi-Fi antenna 7, a switch 8, a power connector 9 and a battery connector 10.

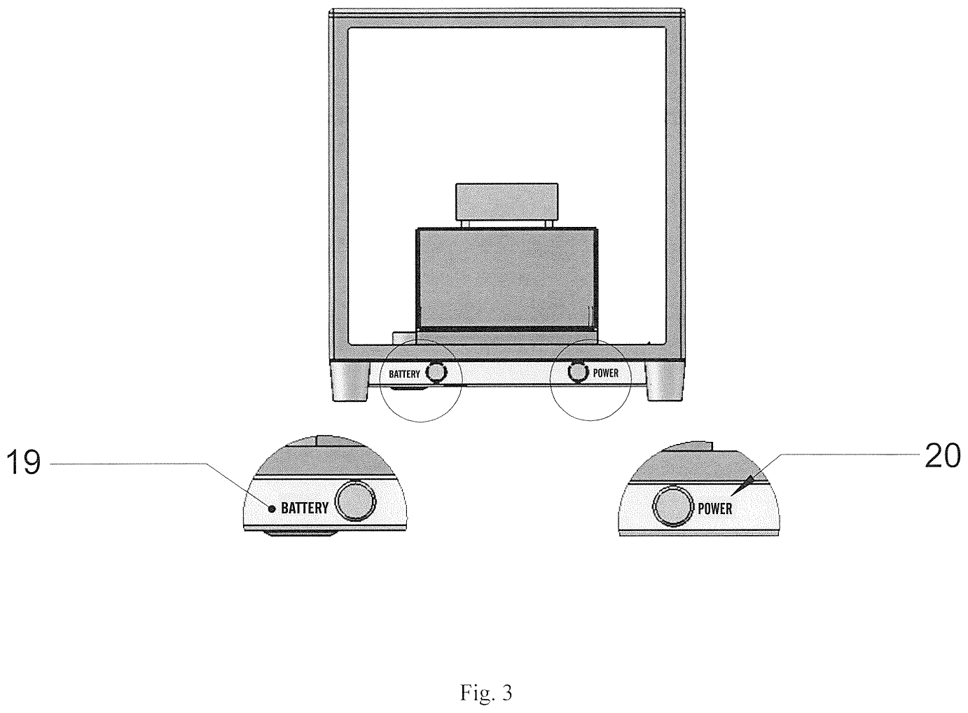

FIG. 3 illustrates a side view of the present invention in its cube embodiment, showing one screen and internal components. The digital display device includes a silkprint battery indicator light and a silkprint power indicator light.

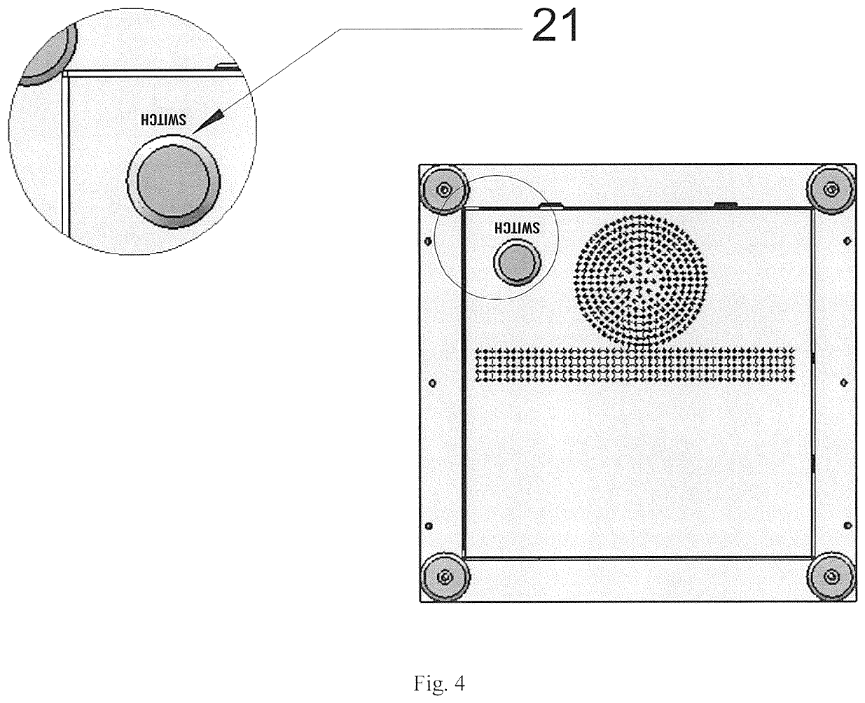

FIG. 4 illustrates a bottom view of the present invention in its cube embodiment, showing the switch. The digital display device includes a silkprint switch.

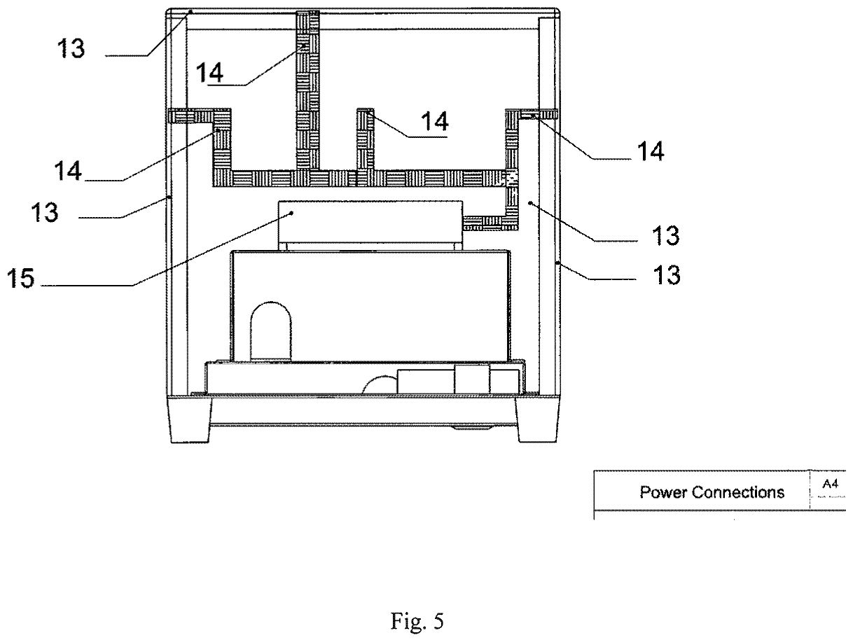

FIG. 5 illustrates a wiring diagram of the present invention in its cube embodiment, showing the power connections. The digital display device includes Light Emitting Diode (LED) modules 13, power lines 14 and a power supply with an output of 5 volts 15.

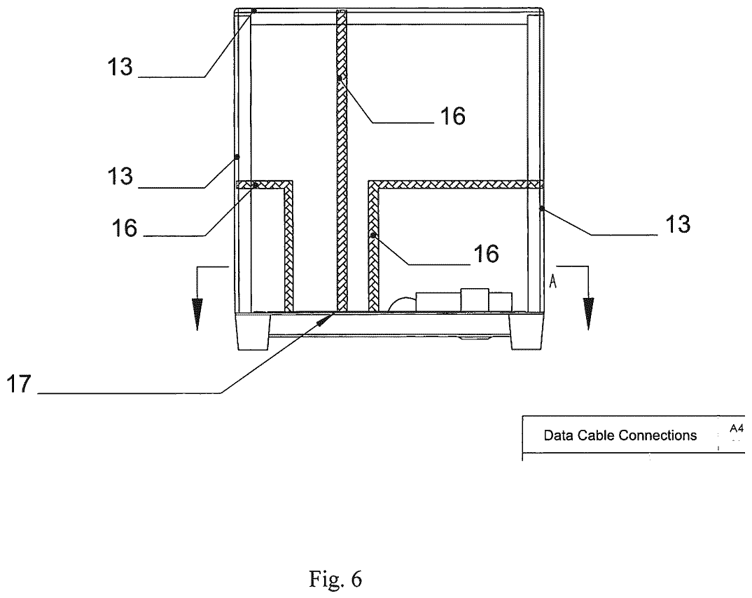

FIG. 6 illustrates the data cable connections of the present invention in its cube embodiment. The digital display device includes Light Emitting Diode (LED) modules 13, and data cables 16.

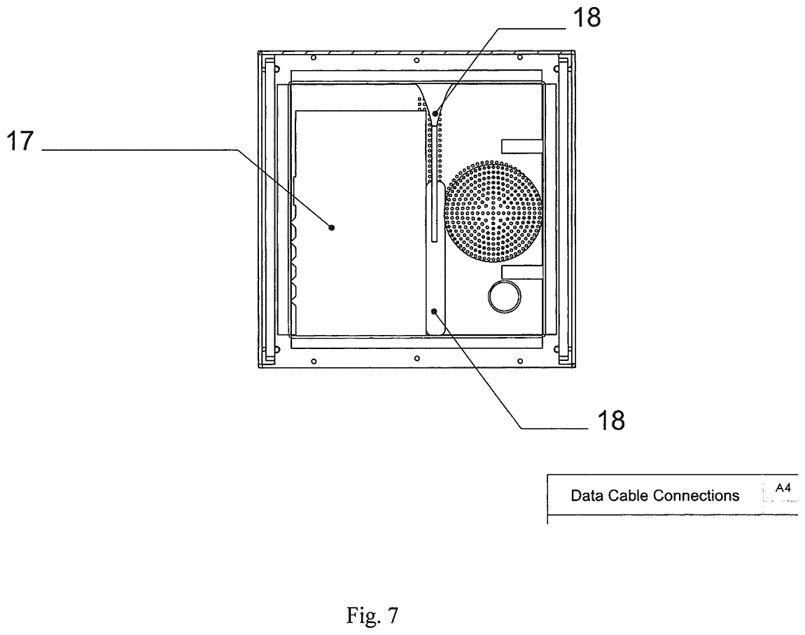

FIG. 7 illustrates a bottom view of the present invention in its cube embodiment, showing the data cable connections. The digital display device includes a control card with Wi-Fi and 4G 17 and two 4G antennas 18.

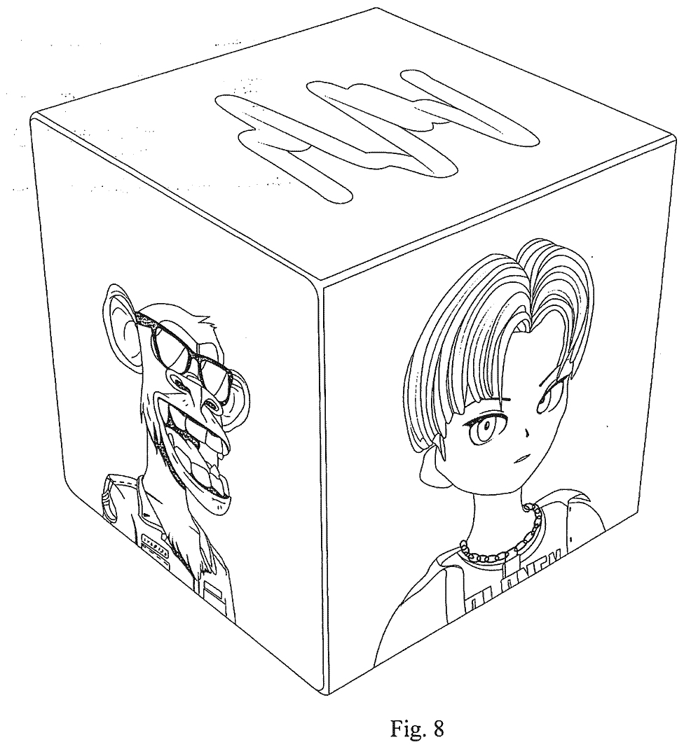

FIG. 8 illustrates a drawing of a top view of the present invention in its cube embodiment, showing images on three screens.

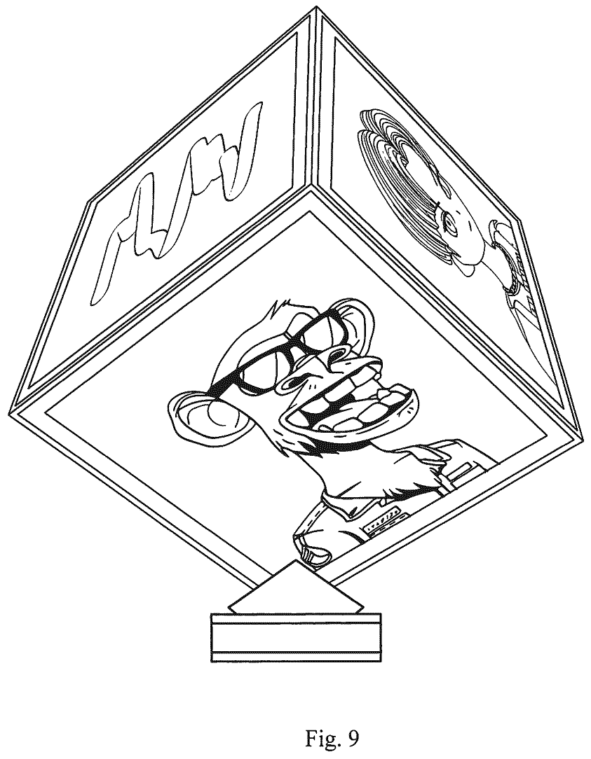

FIG. 9 illustrates a front view of the present invention in its hexagonal embodiment, showing images on three screens.

### ANTICIPATED TECHNICAL SPECIFICATIONS FOR ONE POTENTIAL EMBODIMENT

4G or Wi-Fi connectivity

Free Cloud access, Control content from anywhere

Assign when to display images (date, time)

4 GB Flash memory. Display 1000's of images or dozens of videos.

Cube does not have to be connected to internet to display items. Just upload and go

Image formats supported: BMP, GIF, JPG, PNG, etc

Video formats supported: AVI, WMV, Mp4, 3GP, ASF, MPG, etc

Working temp −10 F to 150 F

Brightness 5,500 nits (outdoor) 900 nits (indoor)

scanning rate 1/27

viewing angle 160 horizontal, 160 vertical

9.75″×9.75″×9.75″ cube has 81,920 Tri-Colour LED's

10 onboard HUB75E ports for smoother motion display.

Pixel pitch (mm): P1.56

Pixel density (dots/m2): 409600

Single-point brightness correction: yes

Single-point color correction: yes

Color Temperature (K): 3200-9300 (adjustable)

Viewing Angle (Horizontal/Vertical): 160/160

Deviation of center distance of light-emitting: <3%

Brightness/chromaticity uniformity: =97%

Contrast 5000:1

Peak power consumption (W/m2): 800

Average power consumption (W/m2): 250

Power supply requirements AC90-264V, frequency 47-63:(Hz)

Frame rate (Hz): 50&60

Drive mode: Constant drive

Grayscale level: 65536

Number of color processing bits: 16 bit

Applicable standards: CCC,TUV-CE,ETL

Additional information is available on the Websites Splashdigitaldisplays.com and Splashdigital.io.

What is claimed is:

1. A digital display device, comprising:
five extremely high resolution screens using liquid crystal displays (LCD) or light emitting diodes (LEDs) joined at their edges by a plastic or metal frame to form a solid polygon with a sixth side which forms a non-displaying base, which screens display still or moving images in a coordinated fashion to create an exhibit or show capable of conveying information and data as well as displaying an artistic show or an event for public entertainment, which images may be self-contained or transferred from a separate user's device by a specially designed application;
wherein the digital display device is powered by a power supply or by an internal battery and controlled by a control card;
wherein a Wi-Fi antenna is contained to receive digital information;
wherein light emitting diodes (LEDs) are contained;
wherein 4G antennas are contained to receive digital information.

2. The digital display device of claim 1, wherein the screens are arranged to form a cube.

3. The digital display device of claim 1, wherein the screens are hexagonal and are connected in the shape of a hexagon.

4. The digital display device of claim 1, wherein four rectangular screens are joined to two square screens, one on each side, to form a rectangular polygon.

5. The digital display device of claim 1, comprised of one spherical screen.

6. A method of displaying digital images, the method comprising:
displaying digital images on five extremely high resolution screens using liquid crystal displays (LCD) or light emitting diodes (LEDs) joined at their edges by a frame constructed of plastic or metal to form a solid polygon with a sixth side which forms a non-displaying base, which screens display still or moving images in a coordinated fashion to create an exhibit or show capable of conveying information and data as well as displaying an artistic show or an event for public entertainment, which images may be self-contained or transferred from a separate user's device by a specially designed application;
wherein the digital display device is powered by a power supply or by an internal battery and controlled by a control card;
wherein a Wi-Fi antenna is contained to receive digital information;
wherein light emitting diodes (LEDs) are contained;
wherein 4G antennas are contained to receive digital information.

7. The method of claim 6, wherein the screens are arranged to form a cube.

8. The method of claim 6, wherein the screens are hexagonal and are connected in the shape of a hexagon.

9. The method of claim 6, wherein four rectangular screens are joined to two square screens, one on each side, to form a rectangular polygon.

10. The method of claim 6, wherein the device is comprised of one spherical screen.
